(19) United States
(12) Patent Application Publication
(10) Pub. No.: US 2013/0084668 A1
(43) Pub. Date: Apr. 4, 2013

(54) TEMPORARY ARC INDUCEMENT OF GLASS SUBSTRATE DURING DIFFUSIVE TRANSPORT DEPOSITION

(71) Applicants: Fred Harper Seymour, Evergreen, CO (US); Jeffrey Todd Knapp, Golden, CO (US); Scott Daniel Feldman-Peabody, Golden, CO (US); Robert Dwayne Gossman, Aurora, CO (US); Mark Jeffrey Pavol, Arvada, CO (US)

(72) Inventors: Fred Harper Seymour, Evergreen, CO (US); Jeffrey Todd Knapp, Golden, CO (US); Scott Daniel Feldman-Peabody, Golden, CO (US); Robert Dwayne Gossman, Aurora, CO (US); Mark Jeffrey Pavol, Arvada, CO (US)

(73) Assignee: PRIMESTAR SOLAR, INC., Arvada, CO (US)

(21) Appl. No.: 13/249,892

(22) Filed: Sep. 30, 2011

(51) Int. Cl. H01L 31/18; C23C 16/458

(52) U.S. Cl. 438/57; 118/729; 257/E31.002

(57) ABSTRACT

Apparatus for vapor deposition of a sublimated source material as a thin film on a photovoltaic module substrate is generally provided. The apparatus can include a deposition head; a distribution plate disposed below said distribution manifold and above an upper surface of a substrate transported through said apparatus and defining a pattern of passages therethrough; and, a carrying mechanism configured to transport the substrate in a machine direction under the distribution plate such that an upper surface of the substrate defines an arc in a cross-direction that is substantially perpendicular to the machine direction. Processes are also generally provided for vapor deposition of a sublimated source material to form thin film on a photovoltaic module substrate.

### FIELD OF THE INVENTION

The subject matter disclosed herein relates generally to the field of thin film deposition processes wherein a thin film layer, such as a semiconductor material layer, is deposited on a substrate. More particularly, the subject matter is related to a vapor deposition apparatus and associated process for depositing a thin film layer of a photo-reactive material (e.g., CdTe) on a glass substrate in the formation of photovoltaic (PV) modules.

### BACKGROUND OF THE INVENTION

Solar energy systems using cadmium telluride (CdTe) photovoltaic (PV) modules are generally recognized as the most cost efficient of the commercially available systems in terms of cost per watt of power generated. However, the advantages of CdTe not withstanding, sustainable commercial exploitation and acceptance of solar power as a supplemental or primary source of industrial or residential power depends on the ability to produce efficient PV modules on a large scale and in a cost effective manner.

Certain factors greatly affect the efficiency of CdTe PV modules in terms of cost and power generation capacity. For example, CdTe is relatively expensive and, thus, efficient utilization (i.e., minimal waste) of the material is a primary cost factor. In addition, the energy conversion efficiency of the module is a factor of certain characteristics of the deposited CdTe film layer. Non-uniformity or defects in the film layer can significantly decrease the output of the module, thereby adding to the cost per unit of power. Also, the ability to process relatively large substrates on an economically sensible commercial scale is a crucial consideration.

CSS (Closed System Sublimation) is a known commercial vapor deposition process for production of CdTe modules. Reference is made, for example, to U.S. Pat. No. 6,444,043 and U.S. Pat. No. 6,423,565. Within the vapor deposition chamber in a CSS system, the substrate is brought to an opposed position at a relatively small distance (i.e., about 2-3 mm) opposite to a CdTe source. The CdTe material sublimes and deposits onto the surface of the substrate. In the CSS system of U.S. Pat. No. 6,444,043 cited above, the CdTe material is in granular form and is held in a heated receptacle within the vapor deposition chamber. The sublimated material moves through holes in a cover placed over the receptacle and deposits onto the stationary glass surface, which is held at the smallest possible distance (1-2 mm) above the cover frame. It is understood that CSS is a type of diffusive transport deposition (DTD) system, and diffusive transport deposition systems, more broadly, need not necessarily qualify as “close spaced” in nature.

A constant supply of CdTe vapors through the hole plate creates a uniform vapor pressure for deposition onto the substrate. Thus, the deposition rate for the entire CdTe layer can be substantially constant, in an effort to ensure that a substantially uniform thin film layer is formed on the substrate. However, if the initial deposition rate it too fast, voids (i.e., small areas free from CdTe) can be created during the initial deposition. These voids can be exaggerated as the deposition process continues.

Additionally, due to the relatively high temperatures involved in the CSS deposition process, the substrate (e.g., a glass superstrate) can be heated to temperatures that can cause an unregulated curved gradient across the face (i.e., the deposition surface) of the substrate. This unregulated curved gradient can add additional variables into the deposition process. For example, a unregulated curved gradient can induce tensions in the substrate, which can lead to damage in the substrate and/or in the thin film formed thereon. Such curved gradients can be particularly problematic when the substrate has a large surface area and is relatively thin, (e.g., on a glass superstrate of a PV module).

Accordingly, there exists an ongoing need in the industry for an improved vapor deposition apparatus and process for economically feasible large scale production of efficient PV modules, particularly CdTe modules. In particular, a need exists for an improved sublimation plate for use in an economically feasible large scale production of efficient PV modules, particularly CdTe modules, in a CSS process.

### BRIEF DESCRIPTION OF THE INVENTION

Aspects and advantages of the invention will be set forth in part in the following description, or may be obvious from the description, or may be learned through practice of the invention.

Apparatus is generally provided for vapor deposition of a sublimated source material as a thin film on a photovoltaic module substrate. The apparatus includes, in one embodiment, a deposition head; a distribution plate disposed below said distribution manifold and above an upper surface of a substrate transported through said apparatus and defining a pattern of passages therethrough; and, a carrying mechanism configured to transport the substrate in a machine direction under the distribution plate such that an upper surface of the substrate defines an arc in a cross-direction that is substantially perpendicular to the machine direction.

Processes are also generally provided for vapor deposition of a sublimated source material to form thin film on a photovoltaic (PV) module substrate. The process can include, in one embodiment, sublimating a source material within a deposition head; conveying individual substrates in a machine direction under a distribution plate on the deposition head such that an upper surface of the substrate defines an arc in a cross-direction that is substantially perpendicular to the machine direction; and, distributing the sublimated source material through a pattern of passages defined in the distribution plate and onto the upper surface of the substrates.

These and other features, aspects and advantages of the present invention will become better understood with reference to the following description and appended claims. The accompanying drawings, which are incorporated in and constitute a part of this specification, illustrate embodiments of the invention and, together with the description, serve to explain the principles of the invention.

### BRIEF DESCRIPTION OF THE DRAWINGS

A full and enabling disclosure of the present invention, including the best mode thereof, directed to one of ordinary skill in the art, is set forth in the specification, which makes reference to the appended figures, in which:

FIG. 1 is a plan view of a system that may incorporate embodiments of a vapor deposition apparatus of the present invention;

FIG. 2 is a cross-sectional view of an embodiment of a vapor deposition apparatus according to aspects of the invention in a first operational configuration;

FIG. 3 is a cross-sectional view of the embodiment of FIG. 2 in a second operational configuration and in cooperation with a substrate conveyor;

FIG. 4 is a cross-sectional view of one embodiment of FIG. 3 (from a side view that is 90° to the view of FIG. 3);

FIG. 5 is a cross-sectional view of another embodiment of FIG. 3 (from a side view that is 90° to the view of FIG. 3);

FIG. 6 is a cross-sectional view of another embodiment of FIG. 3 (from a side view that is 90° to the view of FIG. 3);

FIG. 7 is a bottom view of one embodiment of a hole plate for use with any of the embodiments shown in FIGS. 4-6;

FIG. 8 is a bottom view of another embodiment of a hole plate for use with any of the embodiments shown in FIGS. 4-6;

FIG. 9 is a cross-sectional view of another embodiment of FIG. 3 (from a side view that is 90° to the view of FIG. 3);

FIG. 10 is a cross-sectional view of another embodiment of FIG. 3 (from a side view that is 90° to the view of FIG. 3);

FIG. 11 is a bottom view of one embodiment of the hole plate for use in accordance with the embodiment shown in FIG. 10;

FIG. 12 is a bottom view of another embodiment of the hole plate for use in accordance with the embodiment shown in FIG. 10; and,

FIG. 13 is a cross-sectional view of another embodiment of FIG. 3 (from a side view that is 90° to the view of FIG. 3).

### DETAILED DESCRIPTION OF THE INVENTION

Reference now will be made in detail to embodiments of the invention, one or more examples of which are illustrated in the drawings. Each example is provided by way of explanation of the invention, not limitation of the invention. In fact, it will be apparent to those skilled in the art that various modifications and variations can be made in the present invention without departing from the scope or spirit of the invention. For instance, features illustrated or described as part of one embodiment can be used with another embodiment to yield a still further embodiment. Thus, it is intended that the present invention covers such modifications and variations as come within the scope of the appended claims and their equivalents.

In the present disclosure, when a layer is being described as “on” or “over” another layer or substrate, it is to be understood that the layers can either be directly contacting each other or have another layer or feature between the layers. Thus, these terms are simply describing the relative position of the layers to each other and do not necessarily mean “on top of” since the relative position above or below depends upon the orientation of the device to the viewer. Additionally, although the invention is not limited to any particular film thickness, the term “thin” describing any film layers of the photovoltaic device generally refers to the film layer having a thickness less than about 10 micrometers (“microns” or “μm”).

It is to be understood that the ranges and limits mentioned herein include all ranges located within the prescribed limits (i.e., subranges). For instance, a range from about 100 to about 200 also includes ranges from 110 to 150, 170 to 190, 153 to 162, and 145.3 to 149.6. Further, a limit of up to about 7 also includes a limit of up to about 5, up to 3, and up to about 4.5, as well as ranges within the limit, such as from about 1 to about 5, and from about 3.2 to about 6.5.

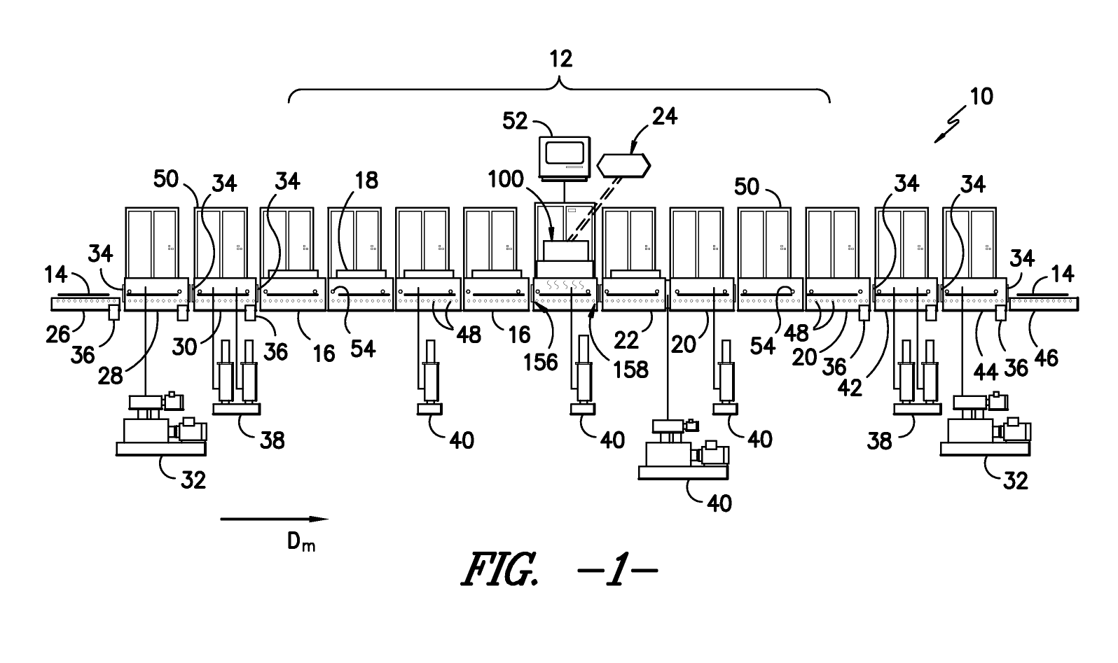

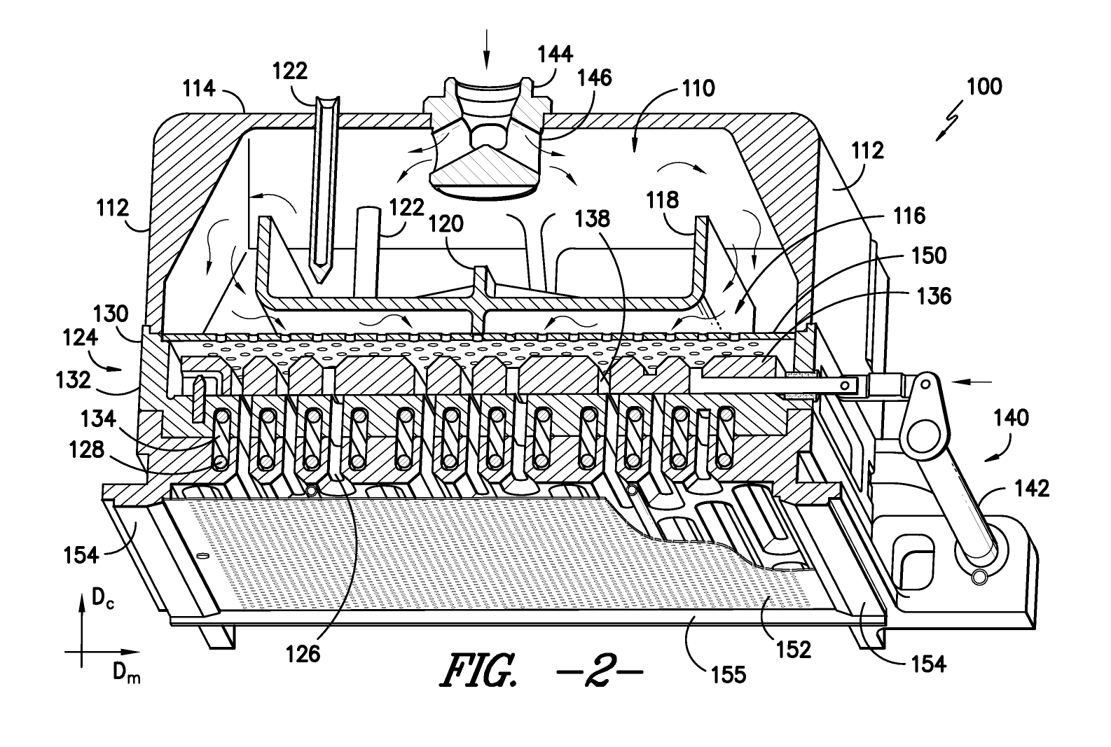

FIG. 1 illustrates an embodiment of a system 10 that may incorporate a vapor deposition apparatus 100 (FIGS. 2-3) in accordance with embodiments of the invention configured for deposition of a thin film layer on an arcuate surface 15 of a photovoltaic (PV) substrate 14 (referred to hereafter as a “substrate”). The thin film may be, for example, a film layer of cadmium telluride (CdTe). As mentioned, it is generally recognized in the art that a “thin” film layer on a PV module substrate is generally less than about 10 microns (μm).

The vapor deposition apparatus 100, which may be described as a diffusive transport deposition system, includes a distribution plate 152 disposed below the distribution manifold 124 at a defined distance above a horizontal plane of the upper surface of an underlying substrate 14, as depicted in FIG. 3. The distribution plate 152 defines a pattern of passages, such as holes, slits, and the like, therethrough that further distribute the sublimated source material passing through the distribution manifold 124 such that the source material vapors are uninterrupted in the transverse direction T. In other words, the pattern of passages are shaped and staggered or otherwise positioned to ensure that the sublimated source material is deposited completely over the substrate in the transverse direction so that longitudinal streaks or stripes of “un-coated” regions on the substrate are avoided.

As the substrates 14 pass under the distribution plate 152 in the vapor deposition apparatus 100, the substrates define an arcuate surface 15 for deposition of the sublimated vapors thereon. The arcuate surface 15 can allow for control of any curve gradient in the substrate 14, which can be induced through heating the substrate 14 and/or due to the weight thereof. As used herein, the terms “arc” and “arcuate” describe a curved, bent, bowed, or otherwise rounded shape, but does not necessarily mean a portion of a circle. It is to be understood that the provision of such a regulated arcuate curvature within the substrate 14 can help deter warpage and/or waviness thereof by reducing the degrees of freedom available for such warpage or waviness.

The arcuate surface 15 can be induced in the substrate 14 during heating of the substrate (e.g., through a series of heater modules 16) prior to passage into the vapor deposition apparatus 100 or during passage into the vapor deposition apparatus 100. In one particular embodiment, the substrates 14 can enter and exit the chamber 12 as a substantially flat substrate 14 (i.e., without any bending forces applied to the substrate 12), can be deformed within the chamber 12 to become arcuate during deposition of a thin film in the vapor deposition apparatus 100, and can return to its substantially flat shape during cooling of the substrates 14.

As shown, the substrates are transported on a carrying mechanism (e.g., a conveyor, series of rollers, a belt(s), or other transporting mechanism) in the machine-direction D_{M} through the vapor deposition apparatus 100 and under the distribution plate 152. The substrates 14 define an arcuate surface 15 in the cross-direction D_{C}, which is substantially perpendicular to the machine-direction D_{M}.

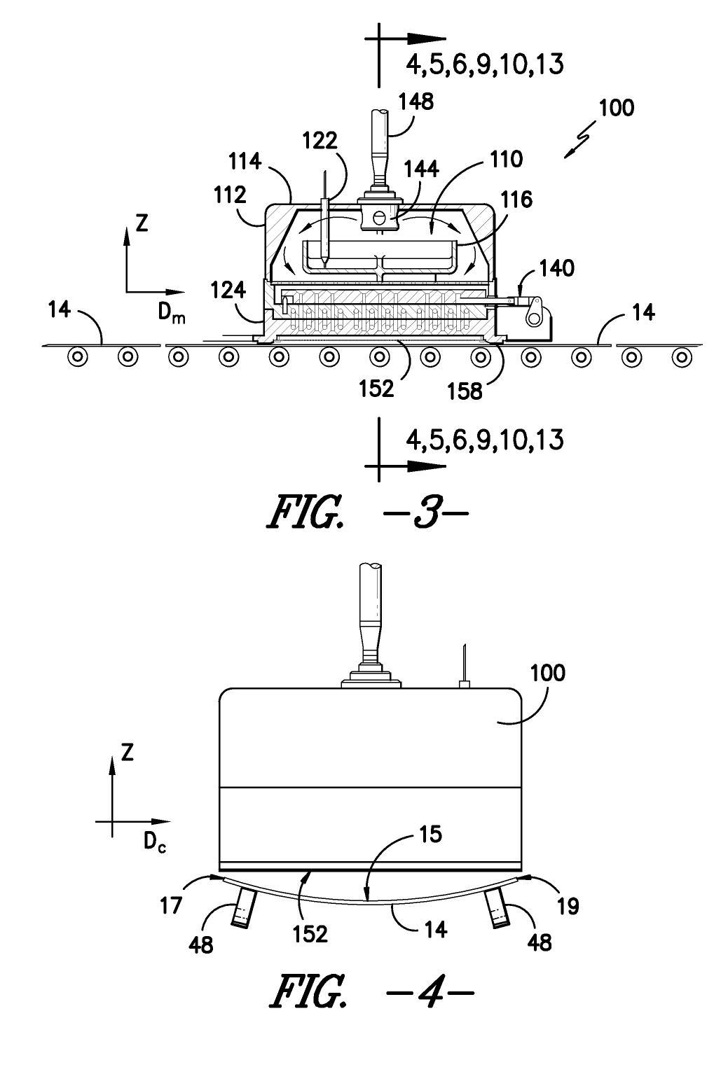

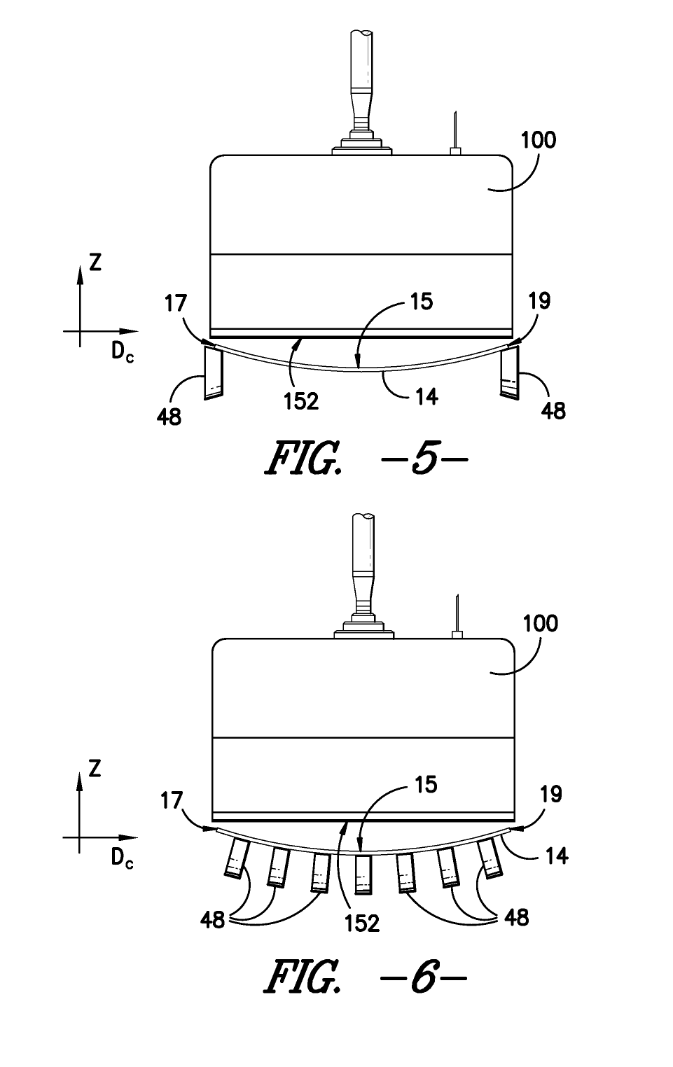

Referring to the embodiments shown in FIGS. 4-7, the substrates 14 define an arcuate surface 15 having a concave arc. In this configuration, the weight of the substrate 12 itself, in combination with the elevated substrate temperature, can allow for the substrate 12 to sag or otherwise deform to form the concave arcuate surface 15. As shown in FIGS. 4-5, the substrate 14 can be allowed to sag on its own weight, controlled by the positioning of the transport members 48 (e.g., rollers, conveyors, etc.) between the lateral edges 17, 19 of the substrate 14 and/or the substrate temperature. For example, FIG. 5 shows the substrate 14 only supported at its lateral edges 17, 19 to allow the arcuate surface 15 to form by sagging of the middle portion between the lateral edges 17, 19. Such an embodiment may be particularly useful with relatively small substrates in the cross-direction D_{C} (e.g., having a width of about 50 cm to about 1 meter).

Alternatively, FIG. 6 shows an embodiment where the amount of bending in the arcuate surface 15 is further controlled by the inclusion of additional transport members 48 under the middle portion of the substrate 14 between the lateral edges 17, 19. Such an embodiment may be particularly useful with relatively large substrates in the cross-direction D_{C} (e.g., having a width of about 1 meter to about 3 meters).

The arcuate surface 15 can define an arc that has a height (H_{A}), which is a measure of the distance from one lateral edge 17 or 19 (as the highest point in the z-direction) to the middle portion (as the lowest point in the z-direction) in a z-direction that is perpendicular to both the machine direction and the cross-direction. In most embodiments, the arc height can be greater than the thickness of the substrate. However, the arc height may be a function of the size (i.e., length in the cross-direction) of the substrate 14. For example, for substrates 14 having a length of about 0.5 mm to about 2.0 mm in the cross-direction and a thickness of about 0.5 mm to about 3.5 mm in the z-direction, the arc height can be about 1.5 mm to about 20 mm.

Due to the arcuate surface 15 of the substrate 14, a distance gradient is formed in the embodiments shown in FIGS. 3-6 between the distribution plate 152 and the arcuate surface 15. Specifically, the lateral edges 17, 19 of the substrate 14 are closer to the distribution plate 152 than the sagging middle portion.

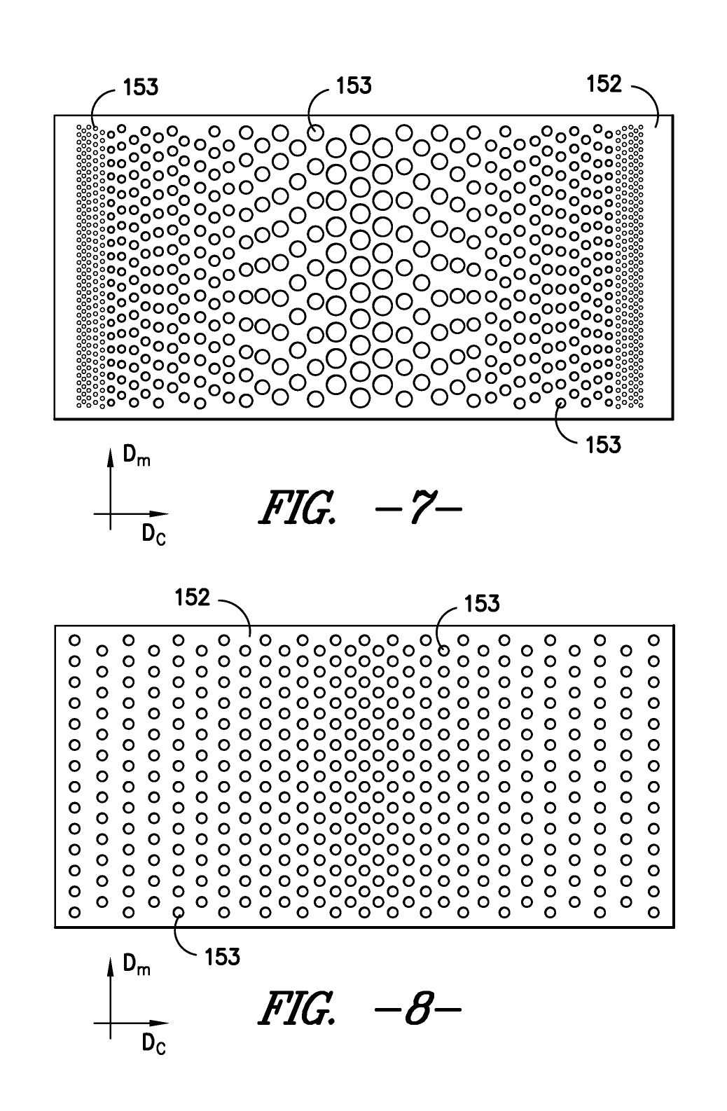

In order to overcome any deposition rate gradient across the arcuate surface 15 that could form due to this distance gradient, the flow rate of the sublimated source material through the distribution plate 152 can be controlled in the cross-direction. For example, in particular embodiments, the pattern of passages in the distribution plate 152 can be configured to provide greater resistance to the flow of sublimated source vapors at its lateral ends than a middle section. FIGS. 7 and 8 show exemplary embodiments of such a distribution plate 152, as viewed from an underside that is facing the substrates 14 in the embodiments of FIGS. 3-6.

Referring to the embodiment shown in FIG. 7, for example, the pattern of passages defines passages in the middle section that are larger than passages along the lateral edges. For example, the average area of the passages in the middle section can be about 1.1 to about 2.5 times larger than the average area of the passages along the lateral ends (i.e., the average area of the passages in the middle section is about 110% to about 250% of the average area of the passages along the lateral ends). For instance, the average area of the passages in the middle section can be about 1.5 to about 2 times larger than the average area of the passages along the lateral ends (i.e., the average area of the passages in the middle section is about 150% to about 200% of the average area of the passages along the lateral ends). In the embodiment shown in FIG. 7, the average areas of the passages increases gradually from each lateral end to the middle portion in the cross-direction. The increase in average areas of the passages can be substantially linear increase; however, the pattern can have an increase in average area of the passages in any suitable manner.

As another example, the pattern of passages can define a hole gradient in the cross-direction such that more holes are located in the middle section that along the lateral edges, as shown in FIG. 8. The passages 153 can, in one particular embodiment, have substantially the same average area throughout the distribution plate 152, as shown in FIG. 8. However, combinations and variations of the embodiments shown in FIGS. 7 and 8 can also be employed to control the flow of the sublimated source vapor through the distribution plate 152. In the embodiments of FIGS. 7 and 8, the distribution plate 152 can be substantially planar, as shown in FIGS. 4-6.

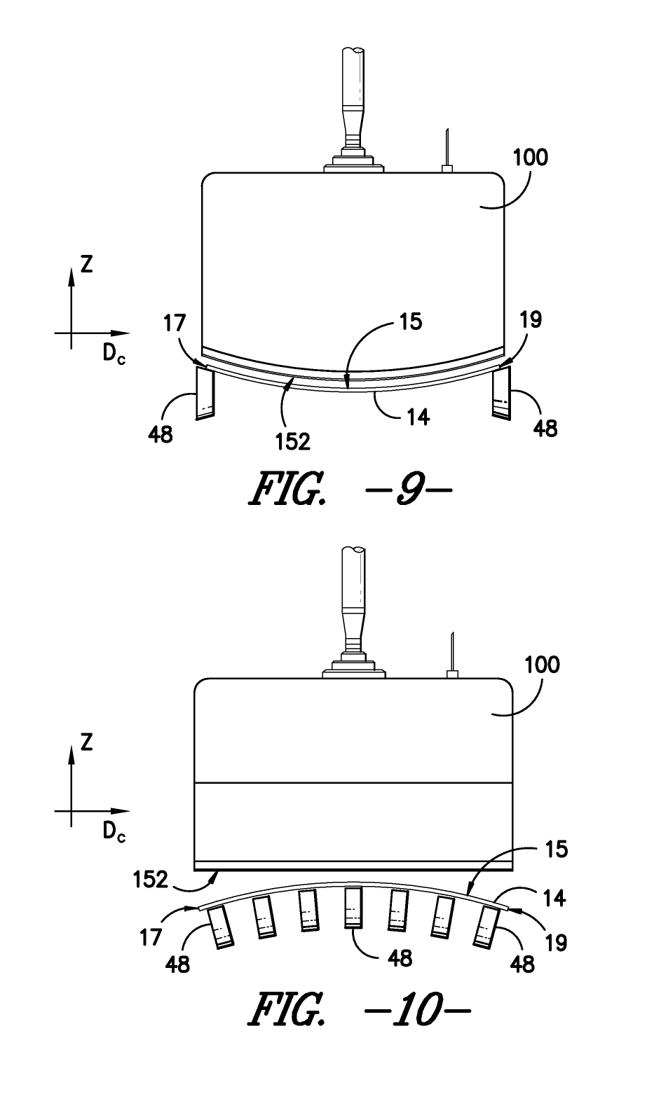

Alternatively, the distribution plate can be bowed such that the distance gradient between the distribution plate 152 and the arcuate surface 15 of the substrate 14 is minimized. Referring to FIG. 9, the distribution plate 152 is shaped to be concave similarly to the arcuate surface such that the distance from the distribution plate 152 to the arcuate surface 15 of the substrate is within a desired range. For instance, the distance between the distribution plate 152 and the arcuate surface 15 at any point, as measured in the z-direction, can be within about 10% of the minimum distance between the closest point of the arcuate surface 15 and the distribution plate 152. In one particular embodiment, substantially parallel to the arcuate surface 15 defined by the substrate 14 such that substantially no distance gradient is present between the arcuate surface 15 and the distribution plate 152.

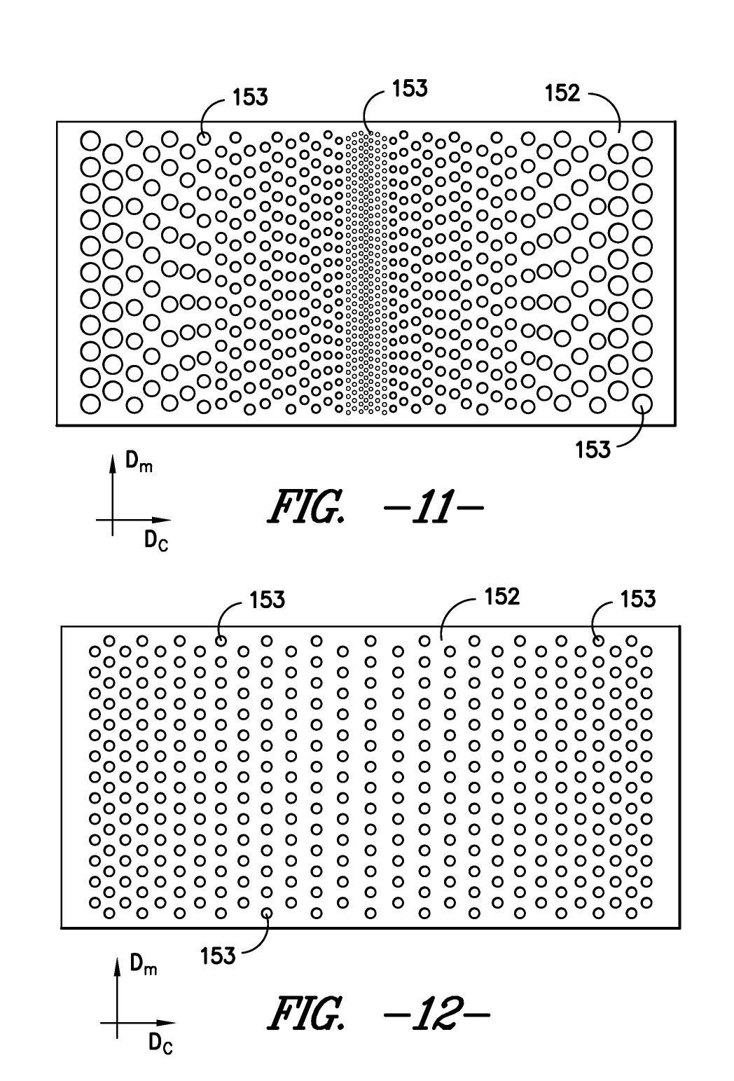

Referring to the embodiments shown in FIGS. 10 and 13, the substrates 14 define an arcuate surface 15 having a convex arc. For example, each lateral edge 17, 19 on the arcuate surface 15 of the substrate 14 is below a middle portion of the arcuate surface 15 of the substrate 14. This convex arc can be formed in the substrates 14 through appropriate positioning of the transport members 48 in the arcuate shaped desired to be formed. In this configuration, the transport mechanism (depicted as rollers 48 in FIGS. 10 and 13) can manipulate the shape of the substrate 14 by forcing the middle portion to rise, and allowing the sides portions and lateral edges 17, 19 to sag (e.g., under their own weight or through a downward force, not shown, applied to each lateral side edge).

As explained above with respect to FIGS. 4-6, the arcuate surface 15 shown in FIGS. 10 and 13 can define an arc that has a height (H_{A}), which is a measure of the distance from one lateral edge 17 or 19 (as the lowest point in the z-direction) to the middle portion (as the highest point in the z-direction) in a z-direction that is perpendicular to both the machine direction and the cross-direction. In most embodiments, the arc height can be greater than the thickness of the substrate. However, the arc height may be a function of the size (i.e., length in the cross-direction) of the substrate 14. For example, for substrates 14 having a length of about 0.5 m to about 2.0 m in the cross-direction and a thickness of about 0.5 mm to about 3.5 mm in the z-direction, the arc height can be about 1.5 mm to about 20 mm.

Due to the arcuate surface 15 of the substrate 14, a distance gradient is formed in the embodiments shown in FIGS. 10 and 13 between the distribution plate 152 and the arcuate surface 15. Specifically, the lateral edges 17, 19 of the substrate 14 are farther from to the distribution plate 152 than the middle portion.

In order to overcome any deposition rate gradient across the arcuate surface 15 that could form due to this distance gradient, the flow rate of the sublimated source material through the distribution plate 152 can be controlled in the cross-direction.

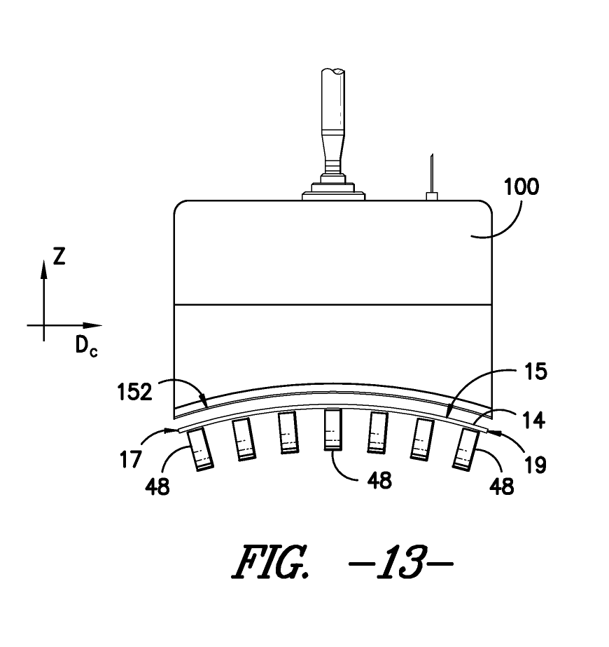

For example, in particular embodiments, the pattern of passages in the distribution plate 152 can be configured to provide greater resistance to the flow of sublimated source vapors at its a middle section than along its lateral ends. FIGS. 11 and 12 show exemplary embodiments of such a distribution plate 152, as viewed from an underside that is facing the substrates 14 in the embodiments of FIGS. 3 and 10.

Referring to the embodiment shown in FIG. 11, for example, the pattern of passages defines passages in the middle section that are smaller than passages along the lateral edges. For example, the average area of the passages along the lateral edges can be about 1.1 to about 2.5 times larger than the average area of the passages in the middle section (i.e., the average area of the passages along the lateral edges is about 110% to about 250% of the average area of the passages in the middle section). For instance, the average area of the passages along the lateral edges can be about 1.5 to about 2 times larger than the average area of the passages in the middle section (i.e., the average area of the passages along the lateral edges is about 150% to about 200% of the average area of the passages in the middle section). In the embodiment shown in FIG. 11, the average areas of the passages decrease gradually from each lateral end to the middle portion in the cross-direction. The decrease in average areas of the passages can be substantially linear decrease; however, the pattern can have an decrease in average area of the passages in any suitable manner.

As another example, the pattern of passages can define a hole gradient in the cross-direction such that fewer holes are located in the middle section that along the lateral edges, as shown in FIG. 12. The passages 153 can, in one particular embodiment, have substantially the same average area throughout the distribution plate 152, as shown in FIG. 12. However, combinations of these embodiments can also be employed to control the flow of the sublimated source vapor through the distribution plate 152. In the embodiments of FIGS. 11 and 12, the distribution plate 152 can be substantially planar, as shown in FIG. 10.

Alternatively, the distribution plate can be bowed such that the distance gradient between the distribution plate 152 and the arcuate surface 15 of the substrate 14 is minimized. Referring to FIG. 13, the distribution plate 152 is shaped to be convex similarly to the arcuate surface 15 such that the distance from the distribution plate 152 to the arcuate surface 15 of the substrate is within a desired range. For instance, the distance between the distribution plate 152 and the arcuate surface 15 at any point, as measured in the z-direction, can be within about 10% of the minimum distance between the closest point of the arcuate surface 15 and the distribution plate 152. In one particular embodiment, substantially parallel to the arcuate surface 15 defined by the substrate 14 such that substantially no distance gradient is present between the arcuate surface 15 and the distribution plate 152.

During use, the distribution plate 152 is heated to a temperature above the temperature of the substrate 14 to ensure that no material deposits and builds up on the distribution plate 152. For example, when depositing a thin film cadmium telluride layer, the substrate 14 may be heated to a substrate temperature between about 550° C. and about 700° C. (e.g., between about 600° C. and about 650° C.) while the distribution plate may be heated to a plate temperature above about 725° C., such as from about 750° C. to about 900° C. (e.g., from about 800° C. to about 850° C.).

No matter the particular configuration, in particular embodiments, the average deposition rate of the entire deposited layer (e.g., a CdTe layer) can be about 5 μm/minute to about 50 μm/minute forming a CdTe layer having a thickness of about 1 μm to about 5 μm (e.g., about 2 μm to about 4 μm).

It should be appreciated that the present vapor deposition apparatus 100 is not limited to use in the system 10 illustrated in FIG. 1, but may be incorporated into any suitable processing line configured for vapor deposition of a thin film layer onto a PV module substrate 14. For reference and an understanding of an environment in which the vapor deposition apparatus 100 may be used, the system 10 of FIG. 1 is described below, followed by a detailed description of the apparatus 100.

Referring to FIG. 1, the exemplary system 10 includes a vacuum chamber 12 defined by a plurality of interconnected modules, including a plurality of heater modules 16 that define a pre-heat section of the vacuum chamber 12 through which the substrates 14 are conveyed and heated to a desired temperature before being conveyed into the vapor deposition apparatus 100. Each of the modules 16 may include a plurality of independently controlled heaters 18, with the heaters defining a plurality of different heat zones. A particular heat zone may include more than one heater 18.

The vacuum chamber 12 also includes a plurality of interconnected cool-down modules 20 downstream of the vapor deposition apparatus 100. The cool-down modules 20 define a cool-down section within the vacuum chamber 12 through which the substrates 14 having the thin film of sublimated source material deposited thereon are conveyed and cooled at a controlled cool-down rate prior to the substrates 14 being removed from the system 10. Each of the modules 20 may include a forced cooling system wherein a cooling medium, such as chilled water, refrigerant, or other medium, is pumped through cooling coils (not illustrated) configured with the modules 20.

In the illustrated embodiment of system 10, at least one post-heat module 22 is located immediately downstream of the vapor deposition apparatus 100 and upstream of the cool-down modules 20 in a conveyance direction of the substrates. As the leading section of a substrate 14 is conveyed out of the vapor deposition apparatus 100, it moves into the post-heat module 22, which maintains the temperature of the substrate 14 at essentially the same temperature as the trailing portion of the substrate still within the vapor deposition apparatus 100. In this way, the leading section of the substrate 14 is not allowed to cool while the trailing section is still within the vapor deposition apparatus 100. If the leading section of a substrate 14 were allowed to cool as it exited the apparatus 100, a non-uniform temperature profile would be generated longitudinally along the substrate 14. This condition could result in the substrate breaking from thermal stress.

As diagrammatically illustrated in FIG. 1, a feed device 24 is configured with the vapor deposition apparatus 100 to supply source material, such as granular CdTe. The feed device 24 may take on various configurations within the scope and spirit of the invention, and functions to supply the source material without interrupting the continuous vapor deposition process within the apparatus 100 or conveyance of the substrates 14 through the apparatus 100.

Still referring to FIG. 1, the individual substrates 14 are initially placed onto a load conveyor 26, and are subsequently moved into an entry vacuum lock station that includes a load module 28 and a buffer module 30. A “rough” (i.e., initial) vacuum pump 32 is configured with the load module 28 to draw an initial vacuum, and a “fine” (i.e., final) vacuum pump 38 is configured with the buffer module 30 to increase the vacuum in the buffer module 30 to essentially the vacuum pressure within the vacuum chamber 12. Slide gates or valves 34 are operably disposed between the load conveyor 26 and the load module 28, between the load module 28 and the buffer module 30, and between the buffer module 30 and the vacuum chamber 12. These valves 34 are sequentially actuated by a motor or other type of actuating mechanism 36 in order to introduce the substrates 14 into the vacuum chamber 12 in a step-wise manner without affecting the vacuum within the chamber 12.

In operation of the system 10, an operational vacuum is maintained in the vacuum chamber 12 by way of any combination of rough and/or fine vacuum pumps 40. In order to introduce a substrate 14 into the vacuum chamber 12, the load module 28 and buffer module 30 are initially vented (with the slide valve 34 between the two modules in the open position). The slide valve 34 between the buffer module 30 and the first heater module 16 is closed. The slide valve 34 between the load module 28 and load conveyor 26 is opened and a substrate 14 is moved into the load module 28. At this point, the first slide valve 34 is shut and the rough vacuum pump 32 then draws an initial vacuum in the load module 28 and buffer module 30. The substrate 14 is then conveyed into the buffer module 30, and the slide valve 34 between the load module 28 and buffer module 30 is closed. The fine vacuum pump 38 then increases the vacuum in the buffer module 30 to approximately the same vacuum in the vacuum chamber 12. At this point, the slide valve 34 between the buffer module 30 and vacuum chamber 12 is opened and the substrate 14 is conveyed into the first heater module 16.

An exit vacuum lock station is configured downstream of the last cool-down module 20, and operates essentially in reverse of the entry vacuum lock station described above. For example, the exit vacuum lock station may include an exit buffer module 42 and a downstream exit lock module 44. Sequentially operated slide valves 34 are disposed between the buffer module 42 and the last one of the cool-down modules 20, between the buffer module 42 and the exit lock module 44, and between the exit lock module 44 and an exit conveyor 46. A fine vacuum pump 38 is configured with the exit buffer module 42, and a rough vacuum pump 32 is configured with the exit lock module 44. The pumps 32, 38 and slide valves 34 are sequentially operated to move the substrates 14 out of the vacuum chamber 12 in a step-wise fashion without loss of vacuum condition within the vacuum chamber 12.

System 10 also includes a transport system (e.g., conveyors, rollers, etc.) configured to move the substrates 14 into, through, and out of the vacuum chamber 12. In the illustrated embodiment, this transport system includes a plurality of individually controlled conveyors 48, with each of the various modules including a respective one of the conveyors 48. It should be appreciated that the type or configuration of the conveyors 48 may vary. In the illustrated embodiment, the conveyors 48 are roller conveyors having rotatably driven rollers that are controlled so as to achieve a desired conveyance rate of the substrates 14 through the respective module and the system 10 overall.

As described, each of the various modules and respective conveyors in the system 10 are independently controlled to perform a particular function. For such control, each of the individual modules may have an associated independent controller 50 configured therewith to control the individual functions of the respective module. The plurality of controllers 50 may, in turn, be in communication with a central system controller 52, as diagrammatically illustrated in FIG. 1. The central system controller 52 can monitor and control (via the independent controllers 50) the functions of any one of the modules so as to achieve an overall desired heat-up rate, deposition rate, cool-down rate, conveyance rate, and so forth, in processing of the substrates 14 through the system 10.

Referring to FIG. 1, for independent control of the individual respective conveyors 48, each of the modules may include any manner of active or passive sensors 54 that detects the presence of the substrates 14 as they are conveyed through the module. The sensors 54 are in communication with the respective module controller 50, which is in turn in communication with the central controller 52. In this manner, the individual respective conveyor 48 may be controlled to ensure that a proper spacing between the substrates 14 is maintained and that the substrates 14 are conveyed at the desired conveyance rate through the vacuum chamber 12.

FIGS. 2-3 relate to a particular embodiment of the vapor deposition apparatus 100. Referring to FIGS. 2 and 3 in particular, the apparatus 100 includes a deposition head 110 defining an interior space in which a receptacle 116 is configured for receipt of a granular source material (not shown). As mentioned, the granular source material may be supplied by a feed device or system 24 (FIG. 1) via a feed tube 148 (FIG. 4). The feed tube 148 is connected to a distributor 144 disposed in an opening in a top wall 114 of the deposition head 110. The distributor 144 includes a plurality of discharge ports 146 that are configured to evenly distribute the granular source material into the receptacle 116. The receptacle 116 has an open top and may include any configuration of internal ribs 120 or other structural elements.

In the illustrated embodiment, at least one thermocouple 122 is operationally disposed through the top wall 114 of the deposition head 110 to monitor temperature within the deposition head 110 adjacent to or in the receptacle 116.

The deposition head 110 also includes longitudinal end walls 112 and side walls. The receptacle 116 can have a shape and configuration such that the end walls of the receptacle 116 are spaced from the end walls 112 of the head chamber 110, while the longitudinal walls of the receptacle 116 lie adjacent to and in close proximation to the side walls of the deposition head so that very little clearance exists between the respective walls. With this configuration, sublimated source material will flow out of the open top of the receptacle 116 and downwardly over the end walls 118 as leading and trailing curtains of vapor over, as depicted in FIGS. 2 and 3.

A heated distribution manifold 124 is disposed below the receptacle 116. This distribution manifold 124 may take on various configurations within the scope and spirit of the invention, and serves to indirectly heat the receptacle 116, as well as to distribute the sublimated source material that flows from the receptacle 116. In the illustrated embodiment, the heated distribution manifold 124 has a clam-shell configuration that includes an upper shell member 130 and a lower shell member 132. Each of the shell members 130, 132 includes recesses therein that define cavities 134 when the shell members are mated together as depicted in FIGS. 2 and 3. Heater elements 128 are disposed within the cavities 134 and serve to heat the distribution manifold 124 to a degree sufficient for indirectly heating the source material within the receptacle 116 to cause sublimation of the source material. The heater elements 128 may be made of a material that reacts with the source material vapor and, in this regard, the shell members 130, 132 also serve to isolate the heater elements 128 from contact with the source material vapor. The heat generated by the distribution manifold 124 is also sufficient to prevent the sublimated source material from plating out onto components of the head chamber 110. Desirably, the coolest component in the head chamber 110 is the upper surface of the substrates 14 conveyed therethrough so as to ensure that the sublimated source material plates onto the substrate, and not onto components of the head chamber 110.

Still referring to FIGS. 2 and 3, the heated distribution manifold 124 includes a plurality of passages 126 defined therethrough. These passages have a shape and configuration so as to uniformly distribute the sublimated source material towards the underlying substrates 14.

In the illustrated embodiment, the distribution plate 152 is disposed below the distribution manifold 124 at a defined distance above a horizontal plane of the upper surface of an underlying substrate 14, as depicted in FIG. 3. This distance may be, for example, between about 0.3 cm to about 4.0 cm. In a particular embodiment, the distance is about 1.0 cm. The conveyance rate of the substrates below the distribution plate 152 may be in the range of, for example, about 10 mm/sec to about 40 mm/sec. In a particular embodiment, this rate may be, for example, about 20 mm/sec. The thickness of the CdTe film layer that plates onto the upper surface of the substrate 14 can vary within the scope and spirit of the invention, and may be, for example, between about 1 micron to about 5 microns. In a particular embodiment, the film thickness may be about 3 microns.

As previously mentioned, a significant portion of the sublimated source material will flow out of the receptacle 116 as leading and trailing curtains of vapor, as depicted in FIG. 2. Although these curtains of vapor will diffuse to some extent in the longitudinal direction prior to passing through the distribution plate 152, it should be appreciated that it is unlikely that a uniform distribution of the sublimated source material in the longitudinal direction will be achieved. In other words, more of the sublimated source material will be distributed through the longitudinal end sections of the distribution plate 152 as compared to the middle portion of the distribution plate. However, as discussed above, because the system 10 conveys the substrates 14 through the vapor deposition apparatus 100 at a constant (non-stop) linear speed, the upper surfaces of the substrates 14 will be exposed to the same deposition environment regardless of any non-uniformity of the vapor distribution along the longitudinal aspect of the apparatus 100. The passages 126 in the distribution manifold 124 and the holes in the distribution plate 152 ensure a relatively uniform distribution of the sublimated source material in the transverse aspect of the vapor deposition apparatus 100. So long as the uniform transverse aspect of the vapor is maintained, a relatively uniform thin film layer is deposited onto the upper surface of the substrates 14 regardless of any non-uniformity in the vapor deposition along the longitudinal aspect of the apparatus 100.

As illustrated in the figures, it may be desired to include a debris shield 150 between the receptacle 116 and the distribution manifold 124. This shield 150 includes holes defined therethrough (which may be larger or smaller than the size of the holes of the distribution plate 152) and primarily serves to retain any granular or particulate source material from passing through and potentially interfering with operation of the movable components of the distribution manifold 124, as discussed in greater detail below. In other words, the debris shield 150 can be configured to act as a breathable screen that inhibits the passage of particles without substantially interfering with vapors flowing through the shield 150.

Referring to FIGS. 2-3, apparatus 100 desirably includes transversely extending seals 154 at each longitudinal end of the head chamber 110. In the illustrated embodiment, the seals define an entry slot 156 and an exit slot 158 at the longitudinal ends of the head chamber 110. These seals 154 are disposed at a distance above the upper surface of the substrates 14 that is less than the distance between the surface of the substrates 14 and the distribution plate 152, as is depicted in FIG. 4. The seals 154 help to maintain the sublimated source material in the deposition area above the substrates. In other words, the seals 154 prevent the sublimated source material from “leaking out” through the longitudinal ends of the apparatus 100. It should be appreciated that the seals 154 may be defined by any suitable structure. In the illustrated embodiment, the seals 154 are actually defined by components of the lower shell member 132 of the heated distribution manifold 124. It should also be appreciated that the seals 154 may cooperate with other structure of the vapor deposition apparatus 100 to provide the sealing function. For example, the seals may engage against structure of the underlying conveyor assembly in the deposition area.

Any manner of longitudinally extending seal structure 155 may also be configured with the apparatus 100 to provide a seal along the longitudinal sides thereof. Referring to FIGS. 2 and 3, this seal structure 155 may include a longitudinally extending side member that is disposed generally as close as reasonably possible to the upper surface of the underlying convey surface so as to inhibit outward flow of the sublimated source material without frictionally engaging against the conveyor.

Referring to FIGS. 2 and 3, the illustrated embodiment includes a movable shutter plate 136 disposed above the distribution manifold 124. This shutter plate 136 includes a plurality of passages 138 defined therethrough that align with the passages 126 in the distribution manifold 124 in a first operational position of the shutter plate 136 as depicted in FIG. 3. As can be readily appreciated from FIG. 3, in this operational position of the shutter plate 136, the sublimated source material is free to flow through the shutter plate 136 and through the passages 126 in the distribution manifold 124 for subsequent distribution through the plate 152. Referring to FIG. 2, the shutter plate 136 is movable to a second operational position relative to the upper surface of the distribution manifold 124 wherein the passages 138 in the shutter plate 136 are misaligned with the passages 126 in the distribution manifold 124. In this configuration, the sublimated source material is blocked from passing through the distribution manifold 124, and is essentially contained within the interior volume of the head chamber 110. Any suitable actuation mechanism, generally 140, may be configured for moving the shutter plate 136 between the first and second operational positions. In the illustrated embodiment, the actuation mechanism 140 includes a rod 142 and any manner of suitable linkage that connects the rod 142 to the shutter plate 136. The rod 142 is rotated by any manner of mechanism located externally of the head chamber 110.

The shutter plate 136 configuration illustrated in FIGS. 2 and 3 is particularly beneficial in that, as desired, the sublimated source material can be quickly and easily contained within the head chamber 110 and prevented from passing through to the deposition area above the conveying unit. This may be desired, for example, during start up of the system 10 while the concentration of vapors within the head chamber builds to a sufficient degree to start the deposition process. Likewise, during shutdown of the system, it may be desired to maintain the sublimated source material within the head chamber 110 to prevent the material from condensing on the conveyor or other components of the apparatus 100.

Referring to FIG. 3, the vapor deposition apparatus 100 may further comprise a transport mechanism disposed below the head chamber 110. In one particular embodiment, this transport mechanism may be configured to induce the arcuate surface 15 in the substrate 14 beginning at the time the substrate passes under the entry slot 156 and then return the substrate 14 to be substantially planar at the time the substrate 14 passes under the exit slot 158. Thus, the arcuate surface 15 can be induced into the substrate entirely within the apparatus 100, such that the embodiments of FIGS. 4-6 9, 10, and 13 are taken as a cross-section view in the middle of the apparatus 100.

The present invention also encompasses various process embodiments for vapor deposition of a sublimated source material to form a thin film on a PV module substrate. The various processes may be practiced with the system embodiments described above or by any other configuration of suitable system components. It should thus be appreciated that the process embodiments according to the invention are not limited to the system configuration described herein.

In a particular embodiment, the vapor deposition process includes supplying source material to a receptacle within a deposition head, and indirectly heating the receptacle with a heat source member to sublimate the source material. The sublimated source material is directed out of the receptacle and downwardly within the deposition head through the heat source member. Individual substrates are conveyed below the heat source member, while defining an arcuate surface. The sublimated source material that passes through the heat source is distributed onto the arcuate surface of the substrates.

This written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they include structural elements that do not differ from the literal language of the claims, or if they include equivalent structural elements with insubstantial differences from the literal languages of the claims.

What is claimed is:

1. An apparatus for vapor deposition of a sublimated source material as a thin film on a photovoltaic module substrate, said apparatus comprising:
a deposition head;
a distribution plate disposed below said distribution manifold and above an upper surface of a substrate transported through said apparatus, wherein the distribution plate defines a pattern of passages therethrough; and,
a carrying mechanism configured to transport the substrate in a machine direction under the distribution plate such that an upper surface of the substrate defines an arc in a cross-direction that is substantially perpendicular to the machine direction.

2. The apparatus as in claim 1, wherein the arc is concave such that each lateral edge on the upper surface of the substrate is above a middle portion of the upper surface of the substrate.

3. The apparatus as in claim 2, wherein the substrate defines a thickness, and wherein the arc has a height defined by the distance from one lateral edge to the middle portion in a z-direction that is perpendicular to both the machine direction and the cross-direction, the height being greater than the thickness of the substrate.

4. The apparatus as in claim 2, wherein the pattern of passages is configured to provide greater resistance to the flow of sublimated source vapors at its lateral ends than a middle section.

5. The apparatus as in claim 4, wherein the pattern of passages defines holes in the middle section that are larger than holes along the lateral edges.

6. The apparatus as in claim 4, wherein the pattern of passages defines a hole gradient in the cross-direction such that more holes are located in the middle section that along the lateral edges.

7. The apparatus as in claim 2, wherein the carrying mechanism is configured to support the substrate only along its lateral edges.

8. The apparatus as in claim 7, wherein the substrate has a width defined between its lateral edges, wherein the width is about 50 cm to about 1 meter.

9. The apparatus as in claim 2, wherein the arc has a height defined by the distance from one lateral edge to the middle portion in a z-direction that is perpendicular to both the machine direction and the cross-direction, the height being greater than the thickness of the substrate, and wherein the substrate is supported between its lateral edges to control the arc height.

10. The apparatus as in claim 9, wherein the substrate has a width defined between its lateral edges, wherein the width is about 1 meter to about 3 meters.

11. The apparatus as in claim 1, wherein the arc is convex such that each lateral edge on the upper surface of the substrate is below a middle portion of the upper surface of the substrate.

12. The apparatus as in claim 11, wherein the arc has a height defined by the distance from one lateral edge to the middle portion in a z-direction that is perpendicular to both the machine direction and the cross-direction, and wherein the height is greater than a thickness in the z-direction of the substrate.

13. The apparatus as in claim 11, wherein the pattern of passages is configured to provide greater resistance to the flow of sublimated source vapors in its middle section than along its lateral ends.

14. The apparatus as in claim 13, wherein the pattern of passages defines holes in the middle section that are smaller than holes along the lateral edges.

15. The apparatus as in claim 13, wherein the pattern of passages defines a hole gradient in the cross-direction such that less holes are located in the middle section that along the lateral edges.

16. The apparatus as in claim 1, wherein the distribution plate is shaped to be substantially parallel to the arc defined by the substrate.

17. A process for vapor deposition of a sublimated source material to form thin film on a photovoltaic module substrate, the process comprising:
sublimating a source material within a deposition head;
conveying individual substrates in a machine direction under a distribution plate on the deposition head such that an upper surface of the substrate defines an arc in a cross-direction that is substantially perpendicular to the machine direction; and,
distributing the sublimated source material through a pattern of passages defined in the distribution plate and onto the upper surface of the substrates.

18. The process as in claim 17, wherein the arc is concave such that each lateral edge on the upper surface of the substrate is above a middle portion of the upper surface of the substrate.

19. The process as in claim 18, wherein the pattern of passages is configured to provide greater resistance to the flow of sublimated source vapors at its lateral ends than a middle section.

20. The process as in claim 18, further comprising:
transporting the substrates through a heating apparatus and under the distribution plate to heat the substrates to a deposition temperature, wherein the substrates are initially substantially planar such that upon heating the substrates are deformed to define the arc.
